(19) United States
(12) Patent Application Publication
(10) Pub. No.: US 2016/0217239 A1
(43) Pub. Date: Jul. 28, 2016

(54) METHOD AND SYSTEM FOR SELECTING STIMULATION SIGNALS FOR POWER ESTIMATION

(71) Applicant: Synopsys, Inc., Mountain View, CA (US)

(72) Inventors: Shekaripuram V. Venkatesh, Los Altos, CA (US); Siddharth Guha, New Delhi (IN); Aman Bansal, Uttar Pradesh (IN)

(73) Assignee: Synopsys, Inc., Mountain View, CA (US)

(21) Appl. No.: 14/603,188

(22) Filed: Jan. 22, 2015

(51) Int. Cl. G06F 17/50; G01R 21/133

(52) U.S. Cl. CPC G06F 17/5036; G06F 17/5045; G01R 21/133

(57) ABSTRACT

A power estimation signal selection tool identifies the signals of an IC design that should be captured in waveform data and activity formats during simulation or emulation. The power estimation signal tool reduces the volume of simulation data produced by a simulator. Signals of at least one specified type are captured in a simulated waveform data (SWD) format. Alternatively, only signals affecting “when” power conditions and abstract RTL expressions are captured in the SWD format, while all other signals are captured in a switching activity data (SAD) format. The signal selections are recorded in memory as a set of simulation directives for capturing those signals during simulation or emulation prior to power estimation. A power estimation tool can read the simulation/emulation data more efficiently and produce sufficiently accurate power estimates.

### TECHNICAL FIELD

This invention relates to integrated circuits power estimation, and in particular to systems, methods and computer program products for such power estimation that are derived from simulation and emulation data, and more particularly that are based upon capture of signals in waveform and activity formats during simulation and emulation of such integrated circuits.

### BACKGROUND ART

The continuing decrease in feature size and the corresponding increase in chip density and operating frequency have made power consumption a major concern in electronic chip design. To control their temperature levels, high power chips require specialized and costly packaging and heat-sink arrangements. This, combined with the recent demand for low-power portable communications and computing systems, has created a need to limit the power consumption in many chip designs.

Electronic chip designers need to get a reasonably accurate power estimate before they tape-out an electronic design for fabrication. Failure to meet the power specifications will result in a costly redesign process.

Overall power consumption depends on switching power, internal power and leakage power. Switching Power depends on the frequency at which a component charges and discharges power. Internal power consists of short circuit power and switching power of components' internal capacitances. Short circuit power is contributed by the flow of charge from power to ground of the component during the brief period when the component is switching logic. Leakage Power is consumed when a component is not switching. It is also called static power. Leakage power depends on how long a component is charged. Power consumption is in general highly dependent on the activity of the chip.

Power estimation tools, such as SpyGlass® Power from Atrenta Inc., use circuit activity and waveform data from simulation or emulation. Most simulation and emulation tools can generate waveform data and/or activity data. The waveform data may be captured as Variable Change Data (VCD) format or as FSDB format and specifies the exact times when signals transition between zero and one. The component activity data is usually captured in Switching Activity Interchange format (SAIF) and gives the frequency at which components switch values.

Today's electronic chip designers choose whether to capture power-estimation simulation data in waveform format (SWD) or in switching activity format (SAD). Waveform data allows the power estimation tool to make accurate power estimates because it allows the power estimation tool to compute switching activity, compute the amount of time that a signal is in the high state, and it allows the tool to estimate the power for cell library components that depend on signal values. Memory cell library components usually have attributes defining their switching, internal and leakage power in terms of signal values.

Switching activity simulation data is much smaller than waveform simulation data. It allows the electronic chip designer to generate a less-accurate power estimate in much less time. It provides less accuracy because it only provides switching activity and doesn't provide signal values.

Electronic chip designers usually generate power estimates using simulation or emulation data based on a technology-mapped design. The technology-mapped design contains the final cell components and signals to be implemented on the chip. Electronic chip designers have a desire to generate power estimates from behavioral simulation data such as those available at the Register-Transfer Level description of the design. The behavioral simulation data is generated earlier in the design cycle and is faster to generate, but the behavioral data provides only a subset of the signals that will be implemented on the chip.

Electronic chip designers want a method of generating a reasonably accurate power estimate in a fast efficient manner.

### SUMMARY DISCLOSURE

A method implemented in a programmed computer system is provided for automatically selecting signals to be captured and used by a power estimation tool in a simulation of a design of an integrated circuit. The programmed computer system comprises at least one processor, and at least one memory coupled to the at least one processor and having stored therein program instructions that direct the at least one processor to carry out the steps of method.

In particular, a high-level description of an integrated circuit design is received into the memory of the programmed computer system. The high-level description of the integrated circuit design may be in the form of a register-transfer level (RTL) netlist with a cell library, or alternatively may be in the form of a technology-mapped gate-level netlist. Then, the computer system's processor(s) identify, from the expressions in the received high-level description, one or more candidate signals of the integrated circuit design.

The processor(s) of the system selects at least a subset of the candidate signals, wherein the selected subset comprises one of (a) signals of at least one specified type for capture in a simulated waveform data (SWD) format or (b) signals affecting “when” power conditions for capture in the SWD format plus all other candidate signals for capture in a switching activity data (SAD) format. The signal selections are recorded in memory as a set of simulation directives for capturing those signals during simulation or emulation prior to power estimation.

In (a) above, specific types of signals that may be selected can include any one or more of clock signals, arithmetic macro interface signals, instantiated cell interface signals, hierarchical terminal signals, domain-crossing nets and signals, enable signals, finite state machine (FSM) control signals, first-in first-out (FIFO) control signals, multiplexer select signals, convergent node signals, divergent node signals, re-convergent node signals and signals that contribute significantly to power.

Further in (b) above, additional candidate signals that, while not affecting “when” power conditions, are of a type designated as affecting abstract expressions in the received high-level description of the integrated circuit design, may also be selected and recorded for capture in an SWD format and a further set of simulation directives for these additional candidate signals saved in memory.

### BRIEF DESCRIPTION OF THE DRAWINGS

FIG. 1 shows examples of convergent, divergent and re-convergent logic.

FIG. 2 shows a flowchart outlining the steps of the power estimation signal selection tool (PSST) when dealing with a design without deep combinational logic or a relatively small percentage of combinational logic.

FIG. 3 shows a flowchart outlining the steps of the PSST when dealing with a design with deep combinational logic or a large percentage of combinational logic.

FIG. 4 shows a block diagram of a PSST.

FIG. 5 shows an example design.

### DETAILED DESCRIPTION

A power estimation signal selection tool (PSST) identifies the signals of an integrated circuit (IC) design that should be captured in waveform data (SWD) and switching activity (SAD) formats during simulation or emulation. The PSST reduces the volume of simulation data produced by a simulator. A power estimation tool (PET) can read the simulation/emulation data more efficiently and produce sufficiently accurate power estimates.

For designs without deep combinational logic or a relatively small percentage of combinational logic, the PSST identifies signals to be captured in SWD format. The PSST examines all the components and signals within the design. The PSST selects signals that connect to specific types of components, control signals, signals with a specific topology and signals that have high influence on power.

For designs with deep combinational logic or a large percentage of combinational logic, the PSST identifies signals to be captured in SWD format and directs that all signals be captured in SAD format. The signals to be captured in SWD format include those that are part of the “when condition” expressions of library cells and those that are part of abstract RTL expressions. The signals in these expressions need to be captured in SWD format so as to capture the expression activity accurately that have a significant influence on the estimated power. The SAD format as described previously does not capture all the adequate information, hence the need to capture in the SWD format for these specific signals. The PSST requires fewer types of signals to be captured in SWD format to generate a sufficiently accurate power estimate.

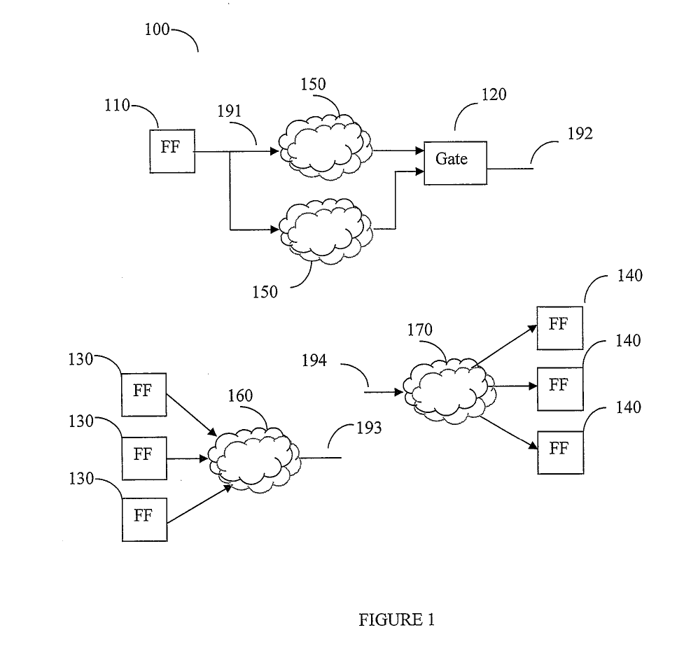

Prior to describing the approaches for the two types of designs, a brief background of convergent, divergent and re-convergent logic in the context of the PSS is warranted. FIG. 1 is a diagram 100 showing convergent, divergent and re-convergent logic.

In diagram 100 the outputs of multiple flip-flops 130 drive a single block of combinational logic 160 creating a single signal 193. If there are many flip-flops 130 driving the combinational logic 160 the statistical propagation may be inaccurate because of the vast logic in the fan-in. The PSST solves these problems by directing the capture of all signals where more than X % of inputs to a combination are observed; in other words the converged signal 193 be captured.

In diagram 100 a signal 194 drives a block of combinational logic 170 creating multiple signals driving flip-flops 140. If the block of combinational logic 170 creates many signals capturing a signal at the source of the combination is important as it will improve the accuracy for all nets where it is observable. The PSST solves these problems by directing the capture of all signals where more than X % of inputs to a combination are observed; in other words the divergent signal 194 be captured.

The flip-flop 110 outputs signal 191 that drives two blocks of combinational logic 150. The two outputs of combinational logic 150 each drive a gate 120 that outputs signal 192. The signal 191 diverges because it drives two blocks of combinational logic. The combinational blocks output two separate signals that converge to one signal 192. In this example the signal 191 diverges and then re-converges to signal 192. A PET applies statistical propagation when it doesn't know the simulation value of a specific signal. It computes a probability that the signal has a high value. The estimation errors increase with the depth of logic. The statistical propagation assumes that all signals are statistically independent and gives an estimate. Convergent logic does not have statistically independent signals. The PSST solves these problems by a) directing that combinational logic signals be captured after every N levels; and b) directing that re-convergent signals are captured.

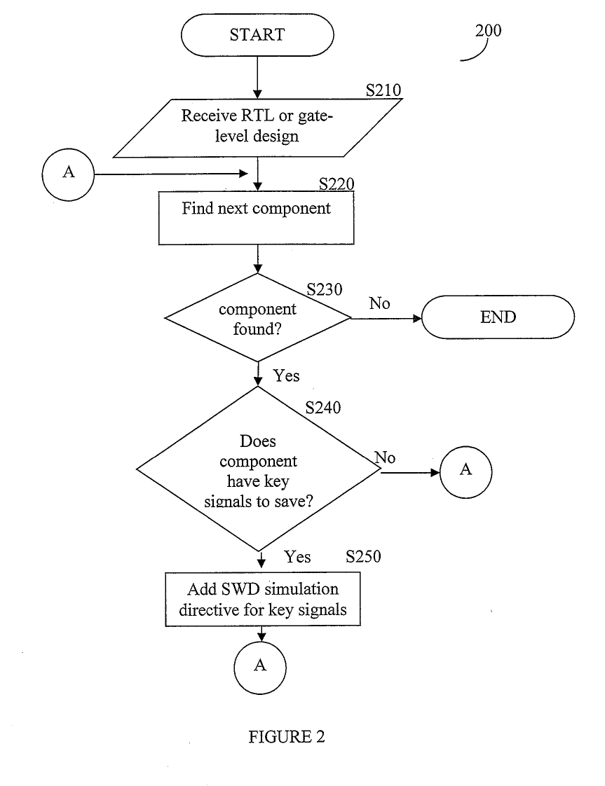

FIG. 2 is an exemplary and non-limiting flowchart 200 for deciding which simulation signals should be captured in a design without deep combinational logic or a relatively small percentage of combinational logic. In S210, the PSST reads the design. The design is in the form of register-transfer-level (RTL) description or a gate-level description. In S220, the PSST starts a loop where it iterates over all the components in the design. On the first iteration it finds the first component. On subsequent iterations it finds the next component. In S230, the PSST checks if the PSST found a next component. If the PSST did not find a next component the PSST exits. If the PSST did find a next component the PSST proceeds to S240.

In S240, the PSST checks if the current component has any input or output signals that need capturing during simulation. If the component has input or output signals that need capturing the PSST proceeds to S250. If the component does not have any input or output signals, that need capturing, the PSST proceeds to S220. The following types of key signals may need capturing during simulation:

### Key Design Signals (Bin 1)

1. Register outputs;
2. Design inputs;
3. Clock signals including derived clocks, master clocks, multiplexed clocks, and gated clocks;
4. Arithmetic macro interface signals including adders, subtractors, accumulators and multipliers;
5. Instantiated cell interface signals including memory and megacells;
6. Signals crossing a hierarchical boundary;
7. Clock domain crossing signals;

### Control Signals (Bin 2)

8. Enable signals;
9. Finite State Machine (FSM) signals;
10. FIFO control signals;
11. Multiplexer select signals;

### Power Essential Signals Based on Design Topology (Bin 3)

12. Re-convergent signals and signals at every n^{th} level of combinational depth;
13. Convergent signals and signals where more than X % of inputs to a combination are observed;
14. Divergent signals and signals where more than X % of inputs to a combination are observed;

### Power Essential Signals Based on Power Contributors of Design Configuration (Bin 4)

15. Signals that cause significant variation in the “when condition” expression of power in library cells. The value of those signals will significantly change the leakage or internal power of the cell.
16. Signals that have high capacitance values
   Any one or more of these bins may be selected by the system for signal collection during a power simulation.

In S250, the PSST records the names of the signals that need capturing during simulation. The PSST writes simulator directives that direct the simulator to capture the specified signals in SWD format.

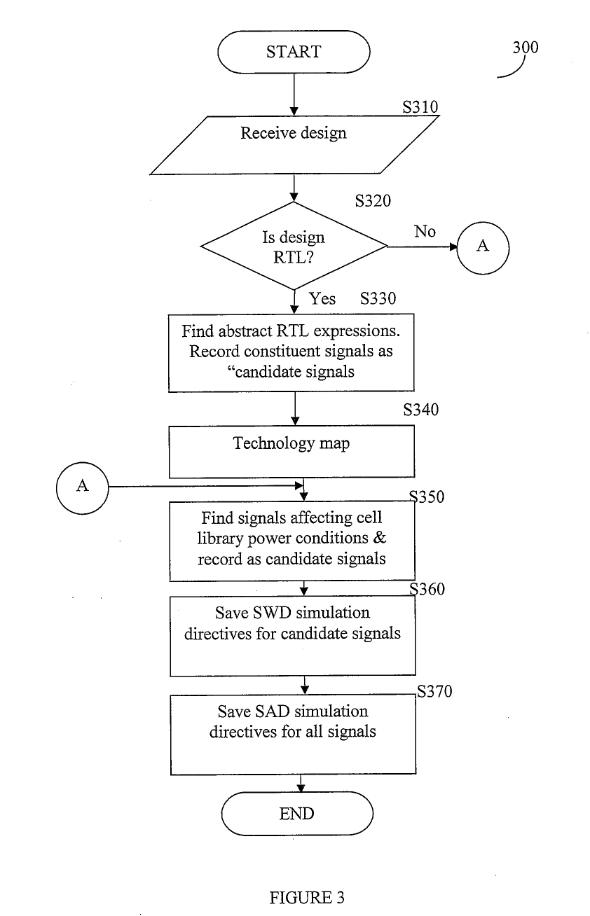

FIG. 3 is an exemplary and non-limiting flowchart 300 for deciding which simulation signals should be captured in a design with deep combinational logic or a large percentage of combinational logic. In S310, the PSST reads the design. The design is in the form of register-transfer-level (RTL) description that has not been technology-mapped or a gate-level description. In S320, the PSST checks if the design is an RTL design. If the design is an RTL design the PSST continues at S330. If the design is not an RTL design the PSST proceeds to S350. In S330, the PSST looks for abstract expressions in the RTL description that don't have a corresponding net in the generated RTL. The PSST records candidate signals referenced by abstract expressions. Enable conditions are often described with abstract expressions. In S340, the PSST technology-maps the RTL design and generates a gate-level netlist.

In S350, the PSST looks for cell library components with power conditions. Memory cell library components often have “when” conditions that define leakage and internal power. The “when” conditions refer to design signals, e.g., “when a&!b&!c” where a, b and c are design signals. The PSST records candidate signals using the nets corresponding to the when conditions. In S360, the PSST records the candidate signals. The PSST writes simulator directives that direct the simulator to capture the candidate signals in SWD format. In S370, the PSST writes simulator directives that direct the simulator to capture all signals in SAD format.

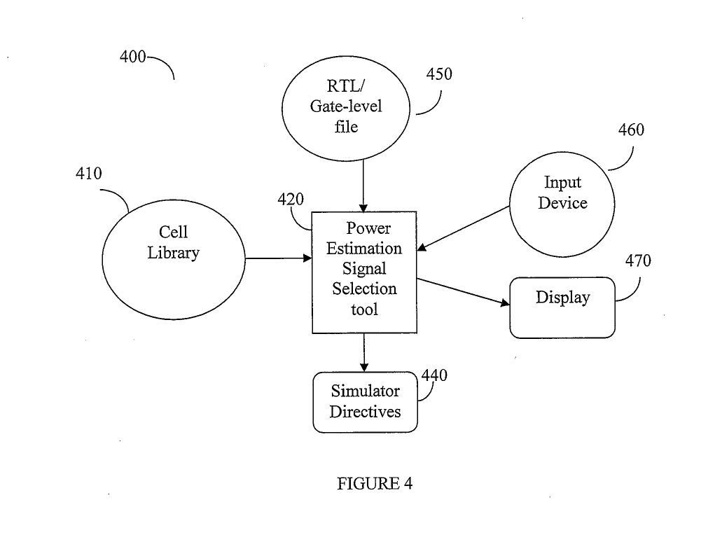

FIG. 4 is an exemplary and non-limiting diagram 400 showing a power estimation signal selection tool (PSST) 420. The PSST 420 runs as an application program on a central processing unit (CPU). In one embodiment the PSST is embedded in an application program that performs related functions such as launching a simulation or estimating the power. The PSST 420 interacts with a logic designer through an input device, 460 and a display, 470. The PSST 420 displays progress on the display, 470. A logic designer specifies PSST inputs, starts the PSST and views progress using the input device 460 and display 470. The PSST 420 reads the RTL or gate-level design 450. In one embodiment the PSST 420 reads the cell library 410 to perform technology mapping when dealing with an RTL design. In a second embodiment the user initiates technology mapping by running a separate application program. The PSST 420 generates simulator directives 440.

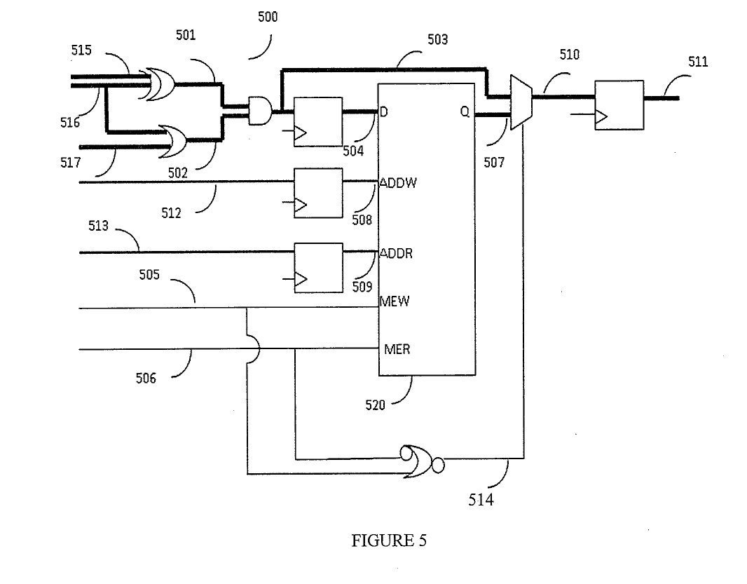

FIG. 5 is a sample logic design 500. Component 520 is an 80-bit memory with 12-bit address lines. Memory component 520 has a D-pin for 80-bit data input, a Q-pin for 80-bit data output, a ADDW-pin for a 12-bit write address, an ADDR-pin for a 12-bit read address, a MEW-pin for memory write enable and a MER-pin for memory read-enable. The D-pin of memory component 520 is driven an 80-bit bus 504 which is driven by 80 1-bit registers. Similarly the ADDW-pin and ADDR-pin are each driven by 12 1-bit registers. Signals 501, 502, 503, 504, 510, 511, 515, 516 and 507 are 80-bit buses. Signals 508, 509, 512 and 513 are 12-bit address lines. Signals 505, 506 and 514 are single-bit enable and select lines. We assume that the design does not have deep combinational logic and we follow the method shown in FIG. 2. The PSST selects signals to capture as follows:
Signals 515, 516, 517, 512, 513, 505 and 506 are all inputs and need to be captured.
Signal 511 is an output and needs to be captured.
Signals 504, 508 and 509 are all register outputs and need to be captured.
Signals 504, 508, 509, 505, 506, and 507 are all memory component inputs and outputs and need to be captured.
Signals 505 and 506 are enables and need to be captured.
Signal 514 is a multiplexer selector and needs to be captured.

The PSST decides that signals 501, 502, 503 and 510 need not be captured. A user first runs the PSST to generate simulation directives for capturing signals, and then runs a power simulator using those simulation directives that were generated by the PSST to capture the selected signals in the specified format(s). Finally, the user runs a power estimation tool to estimate the power based using the simulation results. The power estimation tool estimates the activity and probability of a high-value on each of the un-captured signals 501, 502, 503 and 510.

Consider a 2-input AND-gate with captured input values on signals A and B. A power estimation tool typically characterizes the AND-gate output using formulae:

Activity(output)=(1−Probability(A))×Activity(B)+(1−Probability(B))×Activity(A)

Probability(output)=Probability(A)+Probability(B)+Probability(A)×Probability(B)

The sample logic design above only shows four signals where activity is not captured. But in reality a large number of signals need not be captured. The sample logic design is limited in that sense but it illustrates well the type of key signals whose waveforms have to be captured.

The embodiments disclosed herein can be implemented as hardware, firmware, software, or any combination thereof. Moreover, the software is preferably implemented as an application program tangibly embodied on a program storage unit or computer readable medium. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

What is claimed is:

1. A method implemented in a programmed computer system for automatically selecting signals to be captured and used by a power estimation tool in a simulation of a design of an integrated circuit, the method comprising:
receiving a high-level description of an integrated circuit design into a memory of the programmed computer system;
identifying, by a processor of the programmed computer system, one or more candidate signals of the integrated circuit design, each candidate signal being either a specified type of signal or a signal affecting a “when” power condition;
recording, in the memory, at least a selected subset of the candidate signals, wherein the selected subset comprises one of (a) signals of at least one specified type for capture in a simulated waveform data (SWD) format or (b) signals affecting “when” power conditions for capture in the SWD format plus all signals for capture in a switching activity data (SAD) format; and
saving, in the memory, a set of simulation directives for the recorded candidate signals.

2. The method as in claim 1, wherein the high-level description of the integrated circuit design is in the form of a register-transfer level (RTL) netlist with a cell library.

3. The method as in claim 1, wherein the high-level description of the integrated circuit design is in the form of a technology-mapped gate-level netlist.

4. The method as in claim 1, wherein a first group of the specified types of signals comprise key design signals.

5. The method as in claim 4, wherein the design element and key signals include any one or more of clock signals, arithmetic macro interface signals, instantiated cell interface signals, hierarchical terminal signals and domain-crossing nets of signals.

6. The method as in claim 1, wherein a second group of the specified types of signals comprise control signals.

7. The method as in claim 6, wherein the control signals include any one or more of enable signals, finite state machine (FSM) control signals, first-in first-out (FIFO) control signals, and multiplexer select signals.

8. The method as in claim 1, wherein a third group of the specified types of signals comprise power essential signals based on design topology.

9. The method as in claim 8, wherein the power essential signals based on design topology include any one or more of convergent node signals, divergent node signals, and re-convergent node signals.

10. The method as in claim 1, wherein a fourth group of the specified types of signals comprise power essential signals based on power contributors of design configuration.

11. The method as in claim 1, wherein additional candidate signals are captured in a simulated waveform data (SWD) format that, while not of a type designated as affecting “when” power conditions, are of a type designated as affecting abstract expressions in the received high-level description of the integrated circuit design, and to save a further set of simulation directives for these additional candidate signals, while saving all signals in switching activity data (SAD) format.

12. A programmed computer system for automatically selecting signals to be captured and used by a power estimation tool in a simulation of a design of an integrated circuit, the system comprising:
at least one processor; and
at least one memory coupled to the at least one processor and having stored therein program instructions that direct the at least one processor to:
receive a high-level description of an integrated circuit design into the at least one memory;
identify, by the processor, one or more expressions in the received high-level description representing candidate signals of the integrated circuit design, each candidate signal being either a specified type of signal or a signal affecting a “when” power condition;
record, by the processor, at least a selected subset of the candidate signals, wherein the selected subset comprises one of (a) signals of at least one specified type for capture in a simulated waveform data (SWD) format or (b) signals affecting “when” power conditions for capture in the SWD format plus all signals for capture in a switching activity data (SAD) format; and
save, into the memory, a set of simulation directives for the recorded candidate signals.

13. The system as in claim 12, wherein the high-level description of the integrated circuit design is in the form of a register-transfer level (RTL) netlist with a cell library.

14. The system as in claim 12, wherein the high-level description of the integrated circuit design is in the form of a technology-mapped gate-level netlist.

15. The system as in claim 12, wherein a first group of the specified types of signals comprise key design signals.

16. The system as in claim 15, wherein the design element and key signals include any one or more of clock signals, arithmetic macro interface signals, instantiated cell interface signals, hierarchical terminal signals and domain-crossing nets of signals.

17. The system as in claim 12, wherein a second group of the specified types of signals comprise control signals.

18. The system as in claim 17, wherein the control signals include any one or more of enable signals, finite state machine (FSM) control signals, first-in first-out (FIFO) control signals, and multiplexer select signals.

19. The system as in claim 12, wherein a third group of the specified types of signals comprise power essential signals based on design topology.

20. The system as in claim 19, wherein the power essential signals based on design topology include any one or more of convergent node signals, divergent node signals, and re-convergent node signals.

21. The system as in claim 12, wherein a fourth group of the specified types of signals comprise power essential signals based on power contributors of design configuration.

22. The system as in claim 12, wherein the program instructions further direct the at least one processor to select and record additional candidate signals for capture in a simulated waveform data (SWD) format that, while not of a type designated as affecting “when” power conditions, are of a type designated as affecting abstract expressions in the received high-level description of the integrated circuit design, and to save a further set of simulation directives for these additional candidate signals, while saving all signals in switching activity data (SAD) format.
